(19) United States
(12) Patent Application Publication
(10) Pub. No.: US 2022/0359290 A1
(43) Pub. Date: Nov. 10, 2022

(54) SEMICONDUCTOR STRUCTURE AND MANUFACTURING METHOD THEREOF

(71) Applicant: CHANGXIN MEMORY TECHNOLOGIES, INC., Hefei City (CN)

(72) Inventors: TZUNG-HAN LEE, Hefei City (CN); SHUANGSHUANG WU, Hefei City (CN)

(21) Appl. No.: 17/660,481

(22) Filed: Apr. 25, 2022

(30) Foreign Application Priority Data
May 8, 2021 (CN) 202110500134.X

(51) Int. Cl. H01L 21/768; H01L 23/48

(52) U.S. Cl. CPC H01L 21/76898; H01L 23/481

(57) ABSTRACT

The present disclosure relates to a manufacturing method of a semiconductor structure, including: the base includes an array region and a peripheral region a depth of the TSV is smaller than a thickness of the base; forming a filling dielectric layer; forming a conductive layer in the TSV, the conductive layer is flush with an upper surface of the filling dielectric layer; forming first metal layers an upper surface of each of the first metal layers is flush with an upper surface of the conductive layer; forming a first dielectric layer; and forming a first interconnection structure and second interconnection structures at the same time in the first dielectric layer, a bottom of the first interconnection structure is in contact with one of the first metal layers, and bottoms of the second interconnection structures are in contact with the conductive layer.

### CROSS-REFERENCE TO RELATED APPLICATION

This disclosure claims the priority of Chinese Patent Application No. 202110500134.X submitted to the Chinese Intellectual Property Office on May 8, 2021, the disclosure of which is incorporated herein in its entirety by reference.

### TECHNICAL FIELD

The present disclosure relates to the fields of semiconductor structures and manufacturing thereof, in particular to a semiconductor structure and a manufacturing method thereof.

### BACKGROUND

Through silicon via (TSV) technology is one of the key technologies of 3D packaging processes. The TSV technology can make vertical conduction between dies and between wafers, to realize interconnection between dies.

In the process of interconnecting dies, a metal interconnection structure needs to be built between metal wire layers, and a metal interconnection structure also needs to be established between the TSV structure and other metal wire layers. In the conventional technology, the foregoing two interconnection structures are usually formed in different processes, which are complicated and have low efficiencies.

### SUMMARY

A manufacturing method of a semiconductor structure includes: providing a base, where the base includes an array region and a peripheral region located at a periphery of the array region; forming a TSV in the base of the peripheral region, where a depth of the TSV is smaller than a thickness of the base; forming a filling dielectric layer on an upper surface of the base and sidewalls and a bottom of the TSV; forming a conductive layer in the TSV, where the conductive layer is flush with an upper surface of the filling dielectric layer; forming first metal layers in the filling dielectric layer on the upper surface of the base, where an upper surface of each of the first metal layers is flush with an upper surface of the conductive layer; forming a first dielectric layer on the upper surface of the filling dielectric layer, the upper surface of each of the first metal layers, and the upper surface of the conductive layer; and forming a first interconnection structure and second interconnection structures at the same time in the first dielectric layer, where a bottom of the first interconnection structure is in contact with one of the first metal layers, and bottoms of the second interconnection structures are in contact with the conductive layer.

A semiconductor structure is manufactured by using the manufacturing method of a semiconductor structure according to any one of the foregoing embodiments, and includes: a base, where the base includes an array region and a peripheral region located at a periphery of the array region; a TSV, located in the peripheral region of the base, where a filling dielectric layer is formed on an upper surface of the base and sidewalls and a bottom of the TSV; a conductive layer, formed in the TSV, where the conductive layer is flush with an upper surface of the filling dielectric layer; first metal layers, located in the filling dielectric layer on the upper surface of the base, where an upper surface of each of the first metal layers is flush with an upper surface of the conductive layer; and a first interconnection structure and second interconnection structures, where a bottom of the first interconnection structure is in contact with one of the first metal layers, and bottoms of the second interconnection structures are in contact with the conductive layer.

### BRIEF DESCRIPTION OF THE DRAWINGS

FIG. 1 is a flow block diagram of a manufacturing method of a semiconductor structure according to an embodiment of the present disclosure.

FIG. 2 is a schematic diagram of a cross-sectional structure of a base according to an embodiment of the present disclosure.

FIG. 3 is a schematic diagram of a cross-sectional structure of a semiconductor structure obtained after a TSV is formed according to an embodiment of the present disclosure.

FIG. 4 is a schematic diagram of a cross-sectional structure of the semiconductor structure obtained after a filling dielectric layer is formed according to an embodiment of the present disclosure.

FIG. 5 is a schematic diagram of a cross-sectional structure of the semiconductor structure obtained after a conductive layer is formed according to an embodiment of the present disclosure.

FIG. 6 is a schematic diagram of a cross-sectional structure of the semiconductor structure obtained after a first trench is formed according to an embodiment of the present disclosure.

FIG. 7 is schematic diagram of a cross-sectional structure of the semiconductor structure obtained after a first metal layer is formed according to an embodiment of the present disclosure.

FIG. 8 is schematic diagram of a cross-sectional structure of the semiconductor structure obtained after a first dielectric layer is formed according to an embodiment of the present disclosure.

FIG. 9 is a schematic diagram of a cross-sectional structure of the semiconductor structure obtained after a first interconnection through via and second interconnection through vias are formed according to an embodiment of the present disclosure.

FIG. 10 is schematic diagram of a cross-sectional structure of the semiconductor structure obtained after a first interconnection structure and second interconnection structures are formed according to an embodiment of the present disclosure.

FIG. 11 is a schematic diagram of a three-dimensional structure of the second interconnection structures on an upper surface of the conductive layer according to an embodiment of the present disclosure.

FIG. 12 is a schematic diagram of a cross-sectional structure of the semiconductor structure obtained after second trenches are formed according to an embodiment of the present disclosure.

FIG. 13 is schematic diagram of a cross-sectional structure of the semiconductor structure obtained after a second metal layer is formed according to an embodiment of the present disclosure.

FIG. 14 is a schematic diagram of a cross-sectional structure of a semiconductor structure obtained after a back of the base is thinned according to an embodiment of the present disclosure.

### DETAILED DESCRIPTION

To facilitate the understanding of the present disclosure, the present disclosure is described more completely below with reference to the accompanying drawings. The preferable embodiments of the present disclosure are shown in the accompanying drawings. However, the present disclosure is embodied in various forms without being limited to the embodiments set forth herein. On the contrary, these embodiments are provided to make the understanding of the present disclosure more thorough and comprehensive.

Unless otherwise defined, all technical and scientific terms used herein have the same meaning as commonly understood by those skilled in the technical field of the present disclosure. The terms used in the specification of the present disclosure are merely for the purpose of describing specific embodiments, rather than to limit the present disclosure. The term “and/or” used herein includes any and all combinations of one or more of the associated listed items.

When the positional relationships are described, an element such as a layer, a film or a substrate is referred to as being “on” another layer, it can be directly on the another layer, or an intermediate layer may also be present, unless otherwise specified. Further, when a layer is referred to as being “under” another layer, it can be directly under another layer, and one or more intermediate layers may also be present. It may be also understood that when a layer is referred to as being “between” two layers, it can be the only layer between the two layers, or one or more intermediate layers may also be present.

In a case of using “include”, “have”, and “comprise” described herein, unless an explicit qualifying language is used, such as “only”, “consisting of”, etc., another component may also be added. Unless mentioned to the contrary, a term in the singular manner may appear in the plural manner and should not be construed as the only one.

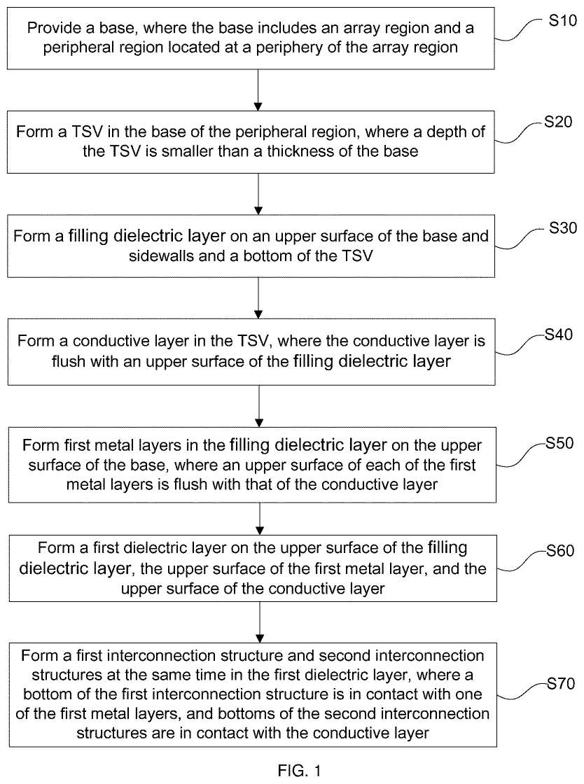

An embodiment of the present disclosure provides a manufacturing method of a semiconductor structure. As shown in FIG. 1, the manufacturing method includes:

S10: Provide a base, where the base includes an array region and a peripheral region located at a periphery of the array region.

S20: Form a TSV in the base of the peripheral region, where a depth of the TSV is smaller than a thickness of the base.

S30: Form a filling dielectric layer on an upper surface of the base and sidewalls and a bottom of the TSV.

S40: Form a conductive layer in the TSV, where the conductive layer is flush with an upper surface of the filling dielectric layer.

S50: Form first metal layers in the filling dielectric layer on the upper surface of the base, where an upper surface of each of the first metal layers is flush with that of the conductive layer.

S60: Form a first dielectric layer on the upper surface of the filling dielectric layer, the upper surface of the first metal layer, and the upper surface of the conductive layer.

S70: Form a first interconnection structure and second interconnection structures at the same time in the first dielectric layer, where a bottom of the first interconnection structure is in contact with one of the first metal layers, and bottoms of the second interconnection structures are in contact with the conductive layer.

The manufacturing method of the semiconductor structure forms the interconnection structures of the array region and the peripheral region while realizing the vertical conduction and interconnection between dies, to simplify the manufacturing process and improve the efficiency.

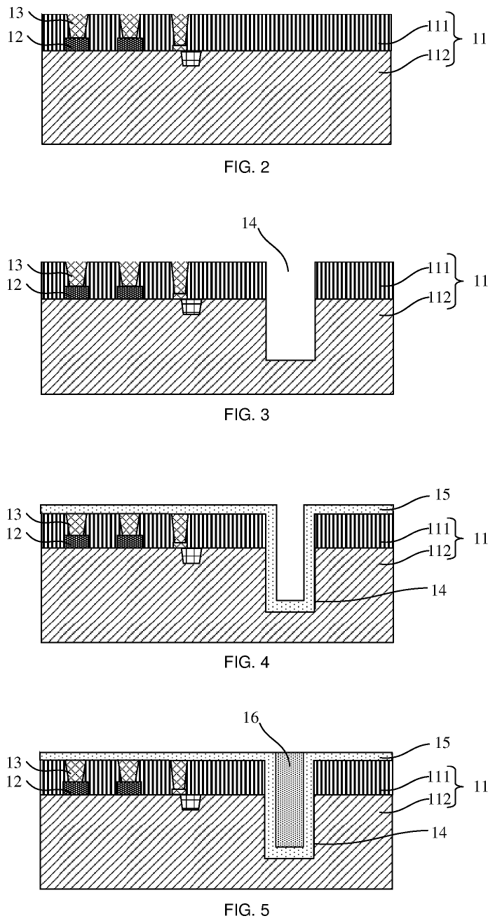

For example, a base 11 in step S10 is shown in FIG. 2. The base 11 includes an array region and a peripheral region located at a periphery of the array region. The array region is provided with device units 12 and interconnection plugs 13. Specifically, the device units 12 may be memory units and/or shallow-trench isolation structure units.

For example, with reference to FIG. 2, the base 11 includes a substrate 112 and a second dielectric layer 111 on an upper surface of the substrate 112. A plurality of device units 12 and interconnection plugs 13 that are arranged in an array are formed in the second dielectric layer 111 of the array region, and a bottom of the interconnection plug 13 is in contact with the device unit 12.

For example, in step S20, a TSV 14 is formed in the base 11 of the peripheral region. As shown in FIG. 3, the TSV 14 runs through the second dielectric layer 111 and partially extends into the substrate 112. A depth of the TSV 14 is smaller than a thickness of the base 11. Specifically, the TSV 14 can be formed by using a photolithography process.

For example, in step S30, a silicon oxide layer may be formed as the filling dielectric layer 15 on the upper surface of the base 11 and the sidewalls and the bottom of the TSV 14 by using processes that are not limited to a physical vapor deposition process, a chemical vapor deposition process, or an atomic layer deposition process. A schematic diagram of a cross-sectional structure of the semiconductor structure obtained after the filling dielectric layer 15 is formed is shown in FIG. 4.

For example, in step S40, the conductive layer 16 may be made of copper. A copper layer may be formed first in the TSV 14 and on the upper surface of the filling dielectric layer 15 through the electroplating process, and then the copper layer on the upper surface of the filling dielectric layer 15 is removed through the chemical-mechanical polishing process, and only the copper layer in the TSV 14 is retained as the conductive layer 16. A schematic diagram of a cross-sectional structure of the semiconductor structure obtained after the conductive layer 16 is formed in the TSV 14 is shown in FIG. 5. The conductive layer 16 is flush with the upper surface of the filling dielectric layer 15.

For example, in step S50, the first metal layers 18 each may be a copper layer. The upper surface of the copper layer is flush with that of the conductive layer 16. Specifically, the step in which the first metal layers 18 are formed in the filling dielectric layer 15 on the upper surface of the base 11 includes:

S51: Form first trenches 17 in the filling dielectric layer 15 on the upper surface of the base 11, where the first trenches 17 expose at least some of the interconnection plugs 13.

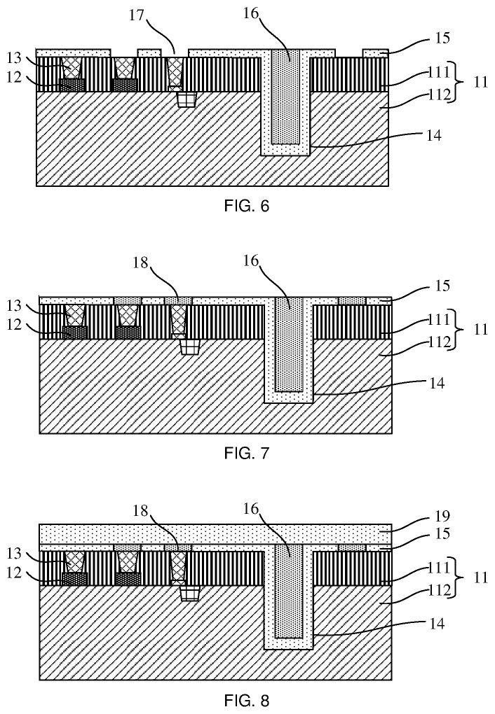

For example, the first trenches 17 may be formed in the filling dielectric layer 15 through the photolithography process. The positions of the first trenches 17 are determined by the photoresist pattern in the photoresist layer. At least some of the first trenches 17 are located in the array region, to expose some of the interconnection plugs 13. At least some of the first trenches 17 are located in the peripheral region. A schematic diagram of a cross-sectional structure of the semiconductor structure obtained after the first trenches 17 are formed is shown in FIG. 6.

S52: Form a first metal material layer in each of the first trenches 17 and on an upper surface of the second dielectric layer 111.

For example, copper layers may be formed as the first metal material layer in each of the first trenches 17 and the first metal material layer on the upper surface of the second dielectric layer 111 through the electroplating process.

S53: Remove the first metal material layer on the upper surface of the second dielectric layer 111.

For example, the copper layer on the upper surface of the second dielectric layer 111 may be polished through the chemical-mechanical polishing process, to remove the copper layer on the upper surface of the second dielectric layer 111. The copper layers in the first trenches 17 are retained as the first metal layers 18. After the copper layer on the upper surface of the second dielectric layer 111 is removed, the upper surfaces of the first metal layers 18 and the filling dielectric layer 15 are flattened through the chemical mechanical polishing process, such that the upper surfaces of the first metal layers 18 are flush with those of the conductive layer 16 and the filling dielectric layer 15. For example, a schematic diagram of a cross-sectional structure of the semiconductor structure obtained after first metal layers 18 are formed in the first trenches 17 is shown in FIG. 7.

For example, as shown in FIG. 8, in step S60, a silicon oxide layer may be formed as the first dielectric layer on the upper surfaces of the filling dielectric layer 15, the first metal layers 18 and the conductive layer 16 through processes that are not limited to a physical vapor deposition process, a chemical vapor deposition process, or an atomic layer deposition process.

For example, in step S70, the first interconnection structure 21a and the second interconnection structures 21b are formed at the same time. The bottom of the first interconnection structure 21a is in contact with one of the first metal layers 18. The top of the first interconnection structure 21a may be further in contact with other metal layers, to be electrically connected to different metal layers. The bottom of the second interconnection structure 21b is in contact with the conductive layer 16. The top of the second interconnection structure 21b may be in contact with another conductive layer 16 or metal layer, such that the conductive layer 16 in the TSV 14 is electrically connected to the another conductive layer 16 or metal layer.

Specifically, the step in which the first interconnection structure 21a and the second interconnection structures 21b are formed in the first dielectric layer at the same time includes:

S71: Form a first interconnection through via 20a and second interconnection through vias 20b in the first dielectric layer, where the first interconnection through via 20a exposes one of the first metal layers 18, and the second interconnection through vias 20b expose the conductive layer 16.

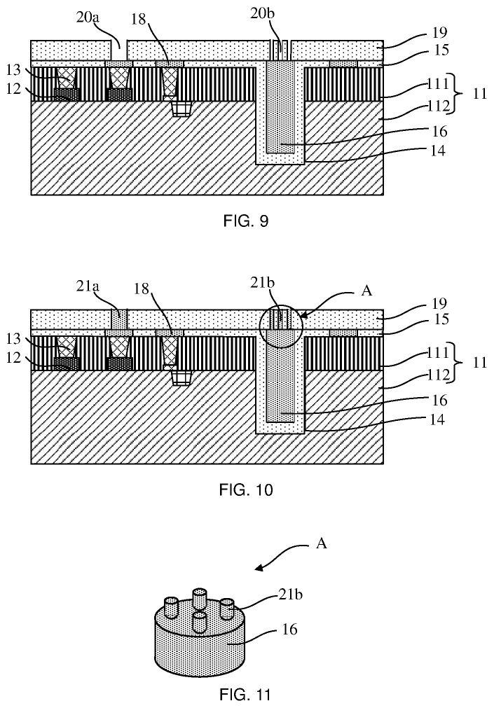

Specifically, the first dielectric layer may be etched through the photolithography process, to form the first interconnection through via 20a and the second interconnection through vias 20b. The second interconnection through vias 20b may include a plurality of cylindrical through vias that are arranged in an array or a grid. The diameter of the cylindrical through via is smaller than that of the conductive layer 16 in the TSV 14. A schematic diagram of a cross-sectional structure of the semiconductor structure obtained after the first interconnection through via 20a and second interconnection through vias 20b are formed in the first dielectric layer is shown in FIG. 9.

S72: Form an interconnection material layer in the first interconnection through via 20a, an interconnection material layer in each of the second interconnection through vias 20b and an interconnection material layer on the upper surface of the first dielectric layer.

S73: Remove the interconnection material layer on the upper surface of the first dielectric layer, retain the interconnection material layer in the first interconnection through via 20a as the first interconnection structure 21a, and retain the interconnection material layer in each of the second interconnection through vias 20b as one of the second interconnection structures 21b.

Specifically, the interconnection material layer may be made of copper. The interconnection material layer in the first interconnection through via 20a, the interconnection material layer in each of the second interconnection through vias 20b and the interconnection material layer on the upper surface of the first dielectric layer may be formed through the electroplating process. Then, the interconnection material layer on the upper surface of the first dielectric layer is removed through the chemical mechanical polishing process. The interconnection material layer in the first interconnection through via 20a and the interconnection material layer in each of the second interconnection through vias 20b are retained, to obtain the first interconnection structure 21a and the second interconnection structures 21b. A schematic diagram of a cross-sectional structure of the semiconductor structure obtained after the first interconnection structure 21a and the second interconnection structures 21b are formed is shown in FIG. 10. A stereoscopic view of the second interconnection structures 21b and a part of the conductive layer 16 in a region A is shown in FIG. 11.

In the process of manufacturing the semiconductor structure, forming the first interconnection structure 21a and the second interconnection structures 21b at the same time can simplify the manufacturing process of the semiconductor structure and improve the product efficiency. Further, the second interconnection structures 21b are at least designed to be of cylindrical structures arranged in an array, to reduce external stress on the conductive layer 16 in the TSV 14 and enlarge the process window.

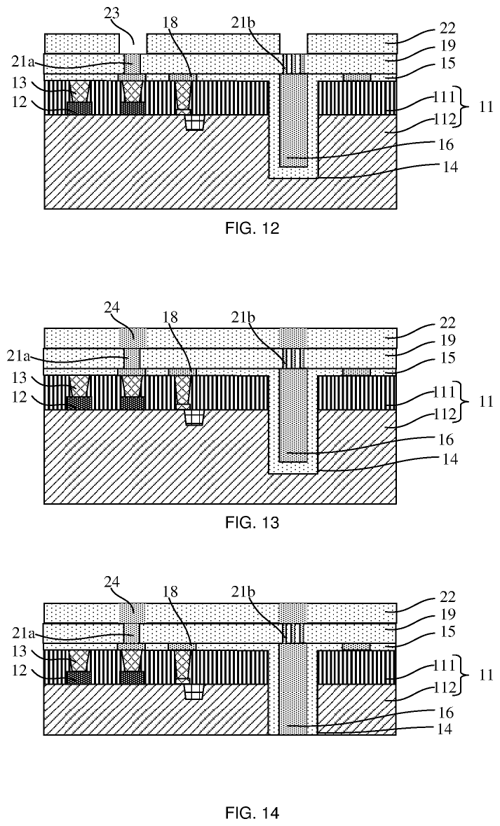

In an embodiment, after the forming a first interconnection structure 21a and second interconnection structures 21b at the same time in the first dielectric layer, the method further includes: forming a third dielectric layer 22 on the upper surface of the first dielectric layer; forming second trenches 23 in the third dielectric layer 22, where the second trenches 23 expose the first interconnection structure 21a and the second interconnection structures 21b; and forming a second metal layer 24 in each of the second trenches 23, where a bottom of one of second metal layers 24 is in contact with the first interconnection structure 21a, and a bottom of another one of the second metal layers 24 is in contact with the second interconnection structures 21b. The step of forming the second metal layer 24 in each of the second trenches 23 includes: forming a second metal material layer in each of the second trenches 23 and a second metal material layer on the upper surface of the third dielectric layer 22; and removing the second metal material layer on the upper surface of the third dielectric layer 22. For example, the process of forming the second metal layer 24 is shown in FIG. 12 and FIG. 13.

In an embodiment, after the forming a second metal layer 24 in each of the second trenches 23, the method further includes: thinning a back of the base 11 until the bottom of the conductive layer 16 is exposed. For example, the back of the base 11 may be thinned through a chemical mechanical polishing process. A schematic diagram of a cross-sectional structure of the semiconductor structure obtained after exposing the bottom of the conductive layer 16 is shown in FIG. 14.

As shown in FIG. 10, a semiconductor structure is manufactured by using the manufacturing method of a semiconductor structure according to any one of the foregoing embodiments, and includes: a base 11, where the base 11 includes an array region and a peripheral region located at a periphery of the array region; a TSV 14, located in a peripheral region of the base 11, where a filling dielectric layer 15 is formed on an upper surface of the base 11 and sidewalls and a bottom of the TSV 14; a conductive layer 16, formed in the TSV 14, where the conductive layer 16 is flush with an upper surface of the filling dielectric layer 15; first metal layers 18, located in the filling dielectric layer 15 on the upper surface of the base 11, where an upper surface of each of the first metal layers 18 is flush with that of the conductive layer 16; and a first interconnection structure 21a and second interconnection structures 21b, where a bottom of the first interconnection structure 21a is in contact with one of the first metal layers 18, and bottoms of the second interconnection structures 21b are in contact with the conductive layer 16.

In an embodiment, the first metal layers 18 are located in the array region and the peripheral region. With reference to FIG. 10, some of the first metal layers 18 are located in the array region, and the other first metal layers 18 are located in the peripheral region.

In an embodiment, an upper surface of the first interconnection structure 21a is flush with upper surfaces of the second interconnection structures 21b.

In an embodiment, there are a plurality of second interconnection structures 21b, and the plurality of second interconnection structures 21b are arranged in an array or a grid on the upper surface of the conductive layer 16. As shown in FIG. 11, there are four second interconnection structures 21b arranged in an array on the upper surface of the conductive layer 16. A diameter of the second interconnection structure 21b is smaller than that of the conductive layer 16. Cylindrical metal structures arranged in an array can reduce external stress on the conductive layer 16 and enlarge the process window.

In an embodiment, the base 11 includes a substrate 112 and a second dielectric layer 111 located on an upper surface of the substrate 112, a plurality of device units 12 and interconnection plugs 13 that are arranged in an array are formed in the second dielectric layer 111 of the array region, and bottoms of the interconnection plugs 13 are in contact with the device units 12. The semiconductor structure further includes a first dielectric layer, formed on the upper surface of the filling dielectric layer 15. As shown in FIG. 10, the first interconnection structure 21a and the second interconnection structures 21b are formed in the first dielectric layer. The device units 12 may be memory units 12 or shallow-trench isolation structure units. The interconnection plug 13 may be a tungsten layer made of metal tungsten.

In an embodiment, the semiconductor structure further includes: a third dielectric layer 22, formed on the upper surface of the first dielectric layer; and second metal layers 24, formed in the third dielectric layer 22, where a bottom of one of the second metal layers 24 is in contact with the first interconnection structure 21a, and a bottom of another one of the second metal layers is in contact with the second interconnection structures 21b.

The technical features of the above examples can be employed in arbitrary combinations. To provide a concise description of these examples, all possible combinations of all technical features of the embodiment may not be described; however, these combinations of technical features should be construed as disclosed in the description as long as no contradiction occurs.

Only several embodiments of the present disclosure are described in detail above, but they should not therefore be construed as limiting the scope of the present disclosure. It should be noted that those of ordinary skill in the art can further make variations and improvements without departing from the conception of the present disclosure. These variations and improvements all fall within the protection scope of the present disclosure. Therefore, the protection scope of the present disclosure should be subject to the protection scope defined by the claims.

1. A manufacturing method of a semiconductor structure, comprising:
providing a base, wherein the base comprises an array region and a peripheral region located at a periphery of the array region;
forming a through silicon via (TSV) in the base of the peripheral region, wherein a depth of the TSV is smaller than a thickness of the base;
forming a filling dielectric layer on an upper surface of the base and sidewalls and a bottom of the TSV;
forming a conductive layer in the TSV, wherein the conductive layer is flush with an upper surface of the filling dielectric layer;
forming first metal layers in the filling dielectric layer on the upper surface of the base, wherein an upper surface of each of the first metal layers is flush with an upper surface of the conductive layer;
forming a first dielectric layer on the upper surface of the filling dielectric layer, the upper surface of each of the first metal layers, and the upper surface of the conductive layer; and
forming a first interconnection structure and second interconnection structures at the same time in the first dielectric layer, wherein a bottom of the first interconnection structure is in contact with one of the first metal layers, and bottoms of the second interconnection structures are in contact with the conductive layer.

2. The manufacturing method of a semiconductor structure according to claim 1, wherein a silicon oxide layer is formed as the filling dielectric layer on the upper surface of the base and the sidewalls and the bottom of the TSV.

3. The manufacturing method of a semiconductor structure according to claim 1, wherein a silicon oxide layer is formed as the first dielectric layer on the upper surface of the filling dielectric layer, the upper surface of each of the first metal layers, and the upper surface of the conductive layer.

4. The manufacturing method of a semiconductor structure according to claim 1, wherein the base comprises a substrate and a second dielectric layer located on an upper surface of the substrate, a plurality of device units and interconnection plugs that are arranged in an array are formed in the second dielectric layer of the array region, and bottoms of the interconnection plugs are in contact with the device units.

5. The manufacturing method of a semiconductor structure according to claim 4, wherein the forming first metal layers in the filling dielectric layer on the upper surface of the base comprises:
forming first trenches in the filling dielectric layer on the upper surface of the base, wherein the first trenches expose at least some of the interconnection plugs;
forming a first metal material layer in each of the first trenches and a first metal material layer on an upper surface of the second dielectric layer; and
removing the first metal material layer on the upper surface of the second dielectric layer.

6. The manufacturing method of a semiconductor structure according to claim 4, wherein each of the device units comprises a memory unit.

7. The manufacturing method of a semiconductor structure according to claim 1, wherein the forming a first interconnection structure and second interconnection structures at the same time in the first dielectric layer comprises:
forming a first interconnection through via and second interconnection through vias in the first dielectric layer, wherein the first interconnection through via exposes one of the first metal layers, and the second interconnection through vias expose the conductive layer;
forming an interconnection material layer in the first interconnection through via, an interconnection material layer in each of the second interconnection through vias and an interconnection material layer on an upper surface of the first dielectric layer; and
removing the interconnection material layer on the upper surface of the first dielectric layer, retaining the interconnection material layer in the first interconnection through via as the first interconnection structure, and retaining the interconnection material layer in each of the second interconnection through vias as one of the second interconnection structures.

8. The manufacturing method of a semiconductor structure according to claim 1, after the forming a first interconnection structure and second interconnection structures at the same time in the first dielectric layer, the manufacturing method further comprises:
forming a third dielectric layer on the upper surface of the first dielectric layer;
forming second trenches in the third dielectric layer, wherein one of the second trenches exposes the first interconnection structure, and another one of the second trenches exposes the second interconnection structures; and
forming a second metal layer in each of the second trenches, wherein a bottom of one of second metal layers is in contact with the first interconnection structure, and a bottom of another one of the second metal layers is in contact with the second interconnection structures.

9. The manufacturing method of a semiconductor structure according to claim 8, wherein the forming a second metal layer in each of the second trenches comprises:
forming a second metal material layer in each of the second trenches and a second metal material layer on an upper surface of the third dielectric layer; and
removing the second metal material layer on the upper surface of the third dielectric layer.

10. The manufacturing method of a semiconductor structure according to claim 8, after the forming a second metal layer in each of the second trenches, the manufacturing method further comprises:
thinning a back of the base until a bottom of the conductive layer is exposed.

11. The manufacturing method of a semiconductor structure according to claim 10, wherein the back of the base is thinned through a chemical mechanical polishing process.

12. A semiconductor structure, manufactured by using the manufacturing method of a semiconductor structure according to claim 1, and comprising:
a base, wherein the base comprises an array region and a peripheral region located at a periphery of the array region;
a TSV, located in the peripheral region of the base, wherein a filling dielectric layer is formed on an upper surface of the base and sidewalls and a bottom of the TSV;
a conductive layer, formed in the TSV, wherein the conductive layer is flush with an upper surface of the filling dielectric layer;
first metal layers, located in the filling dielectric layer on the upper surface of the base, wherein an upper surface of each of the first metal layers is flush with an upper surface of the conductive layer; and
a first interconnection structure and second interconnection structures, wherein a bottom of the first interconnection structure is in contact with one of the first metal layers, and bottoms of the second interconnection structures are in contact with the conductive layer.

13. The semiconductor structure according to claim 12, wherein the first metal layers are located in the array region and the peripheral region.

14. The semiconductor structure according to claim 12, wherein an upper surface of the first interconnection structure is flush with upper surfaces of the second interconnection structures.

15. The semiconductor structure according to claim 12, wherein there are a plurality of second interconnection structures, and the plurality of second interconnection structures are arranged in an array or a grid on the upper surface of the conductive layer.

16. The semiconductor structure according to claim 12, wherein the base comprises a substrate and a second dielectric layer located on an upper surface of the substrate, a plurality of device units and interconnection plugs that are arranged in an array are formed in the second dielectric layer of the array region, and bottoms of the interconnection plugs are in contact with the device units, and the semiconductor structure further comprises:
a first dielectric layer, formed on the upper surface of the filling dielectric layer, wherein the first interconnection structure and the second interconnection structures are formed in the first dielectric layer.

17. The semiconductor structure according to claim 16, the semiconductor structure further comprises:
a third dielectric layer, formed on an upper surface of the first dielectric layer; and
second metal layers, formed in the third dielectric layer, wherein a bottom of one of the second metal layers is in contact with the first interconnection structure, and a bottom of another one of the second metal layers is in contact with the second interconnection structures.

18. The semiconductor structure according to claim 13, wherein there are a plurality of second interconnection structures, and the plurality of second interconnection structures are arranged in an array or a grid on the upper surface of the conductive layer.

19. The semiconductor structure according to claim 14, wherein there are a plurality of second interconnection structures, and the plurality of second interconnection structures are arranged in an array or a grid on the upper surface of the conductive layer.
